(19) United States
(12) Patent Application Publication
(10) Pub. No.: US 2024/0040911 A1
(43) Pub. Date: Feb. 1, 2024

(54) DISPLAY DEVICE AND ELECTRONIC APPARATUS

(71) Applicant: SONY SEMICONDUCTOR SOLUTIONS CORPORATION, KANAGAWA (JP)

(72) Inventors: KEIICHI YAGI, KANAGAWA (JP); CHUGEN HAMACHI, KANAGAWA (JP); YOSUKE MOTOYAMA, KANAGAWA (JP)

(21) Appl. No.: 18/258,220

(22) PCT Filed: Dec. 23, 2021
(86) PCT No.: PCT/JP2021/047892

§ 371 Date: Jun. 19, 2023

(30) Foreign Application Priority Data
Dec. 25, 2020 (JP) 2020-217354

(51) Int. Cl. H10K 59/80; H10K 59/38; H10K 59/35

(52) U.S. Cl. CPC H10K 59/878; H10K 59/38; H10K 59/35

(57) ABSTRACT

Provided is a display device capable of suppressing reflection of light of a visible light region in a peripheral region. The display device includes a reflecting portion, an insulating layer, an electrode, and a filter of a predetermined color that are provided in this order in a region around a display region. The reflecting portion and the electrode constitute a resonator structure, which weakens light of the predetermined color.

### TECHNICAL FIELD

The present disclosure relates to a display device and an electronic apparatus including the display device.

### BACKGROUND ART

A display device such as an organic electroluminescence (EL) display device has a reflecting portion such as a metal layer provided in a region (hereinafter referred to as a “peripheral region”) around a display region, and therefore has a problem that external light is reflected in the peripheral region and stray light or the like is generated. Therefore, in order to suppress the external light reflection, conventionally, a technique of suppressing reflection of light in a visible light region by stacking color filters of two or more colors in the peripheral region has been proposed (for example, see Patent Document 1).

### CITATION LIST

### Patent Document

Patent Document 1: Japanese Patent Application Laid-Open No. 2010-266711

### SUMMARY OF THE INVENTION

### Problems to be Solved by the Invention

As described above, conventionally, a technique for suppressing reflection of light of a visible light region in a peripheral region is desired.

An object of the present disclosure is to provide a display device capable of suppressing reflection of light of a visible light region in a peripheral region, and an electronic apparatus including the display device.

### Solutions to Problems

In order to solve the above problem, a first disclosure is a display device including a reflecting portion, an insulating layer, an electrode, and a filter of a predetermined color that are provided in this order in a region around a display region, in which the reflecting portion and the electrode constitute a resonator structure, and the resonator structure weakens light of the predetermined color.

A second disclosure is an electronic apparatus including the display device of the first disclosure.

A third disclosure is a display device including a reflecting portion, a light absorption portion, an electrode, and a color filter that are provided in this order in a region around a display region, in which the light absorption portion absorbs light that passes through the color filter.

A fourth disclosure is an electronic apparatus including the display device of the third disclosure.

### BRIEF DESCRIPTION OF DRAWINGS

FIG. 1 is a plan view illustrating a configuration example of a display device according to a first embodiment of the present disclosure.

FIG. 2 is a cross-sectional view taken along line II-II of FIG. 1.

FIG. 3 is a graph illustrating a light intensity distribution of a filter and a resonator structure.

FIG. 4 is a cross-sectional view illustrating a configuration example of a display device according to a second embodiment of the present disclosure.

FIG. 5 is a cross-sectional view illustrating a configuration example of a display device according to a third embodiment of the present disclosure.

FIG. 6 is a cross-sectional view illustrating a configuration example of a display device according to a modification.

FIG. 7 is a cross-sectional view illustrating a configuration example of a display device according to a modification.

FIG. 8 is a cross-sectional view illustrating a configuration example of a display device according to a modification.

FIG. 9A is a front view illustrating an example of an external appearance of a digital still camera. FIG. 9B is a back view illustrating an example of an external appearance of the digital still camera.

FIG. 10 is a perspective view illustrating an example of an external appearance of a head mounted display.

FIG. 11 is a perspective view illustrating an example of an external appearance of a television apparatus.

### MODE FOR CARRYING OUT THE INVENTION

Embodiments of the present disclosure will be described in the following order.
1 First embodiment (example of display device)
2 Second embodiment (example of display device)
3 Third embodiment (example of display device)
4 Modification (modification of display device)
5 Application Example (example of electronic apparatus)

### 1 First Embodiment

[Configuration of Display Device]

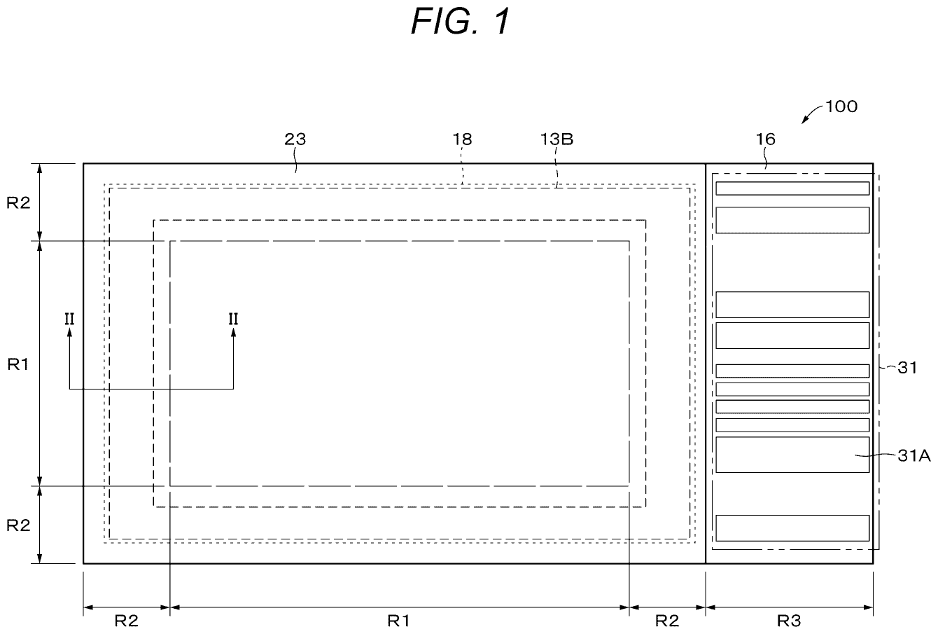

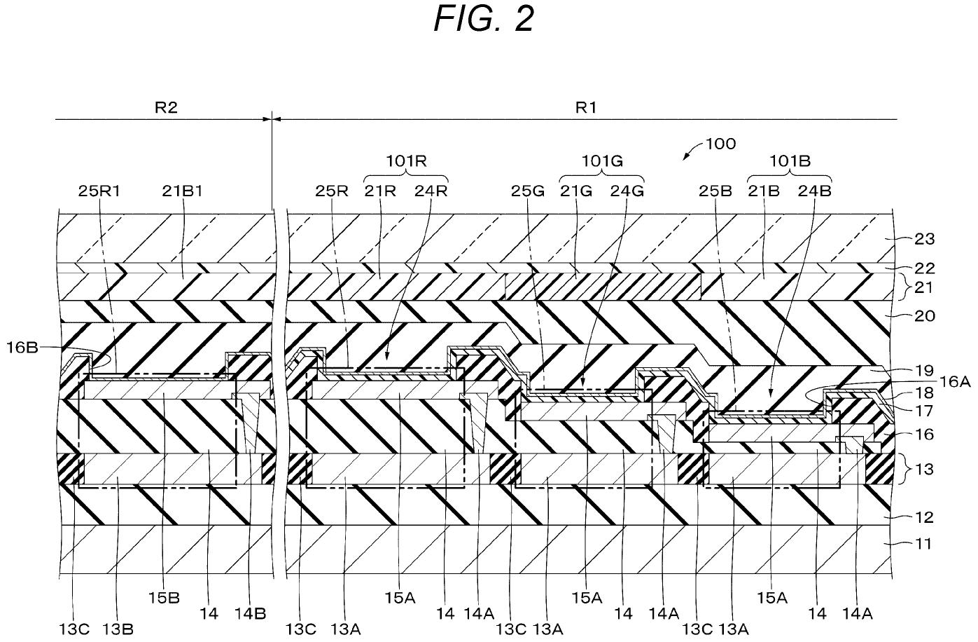

FIG. 1 is a plan view illustrating a configuration example of a display device 100 according to a first embodiment of the present disclosure. FIG. 2 is a cross-sectional view taken along line II-II of FIG. 1. The display device 100 is a so-called organic EL display device. The display device 100 has a display region R1 and a peripheral region R2. In the display region R1, a plurality of subpixels 101R, 101G, and 101B is two-dimensionally arranged in a predetermined arrangement pattern such as a matrix. The peripheral region R2 is provided around the display region R1. The peripheral region R2 has a closed loop shape surrounding the display region R1.

The subpixel 101R displays red, the subpixel 101G displays green, and the subpixel 101B displays blue. Note that, in the following description, in a case where the subpixels 101R, 101G, and 101B are collectively referred to without being particularly distinguished, the subpixels 101R, 101G, and 101B are referred to as subpixels 101. For example, a combination of adjacent subpixels 101R, 101G, and 101B constitutes one pixel.

The display device 100 may further include a connection region R3. A pad portion 31 is provided in the connection region R3. The pad portion 31 is a connection portion for electrically connecting the display device 100 to a main board or the like of the electronic apparatus. The pad portion 31 is provided with a plurality of connection terminals 31A. The pad portion 31 is, for example, connected to the main board of the electronic apparatus and the like with a connection member such as a flexible printed wiring board interposed therebetween.

The display device 100 may be a microdisplay. The display device 100 may be included in a virtual reality (VR) device, a mixed reality (MR) device, an augmented reality (AR) device, an electronic view finder (EVF), a small projector, or the like.

As illustrated in FIG. 2, the display device 100 includes a first substrate 11, an insulating layer 12, a reflective layer 13, an insulating layer 14, a plurality of first electrodes 15A, an insulating layer 16, an organic EL layer 17, a second electrode 18, a third electrode 15B, a protective layer 19, a flattening layer 20, a color filter 21, a filling resin layer 22, and a second substrate 23. However, the flattening layer 20 is provided as necessary, and need not necessarily be provided. The filling resin layer 22 and the second substrate 23 are also provided as necessary, and need not necessarily be provided.

In the display region R1, the first substrate 11, the insulating layer 12, the reflective layer 13, the insulating layer 14, the first electrodes 15A, the organic EL layer 17, the second electrode 18, the protective layer 19, the flattening layer 20, the color filter 21, the filling resin layer 22, and the second substrate 23 are provided in this order.

In the peripheral region R2, the first substrate 11, the insulating layer 12, the reflective layer 13, the insulating layer 14, the third electrode 15B, the second electrode 18, the protective layer 19, the flattening layer 20, the color filter 21, the filling resin layer 22, and the second substrate 23 are provided in this order. Although an example in which the third electrode 15B is provided in the peripheral region R2 will be described in the first embodiment, the third electrode 15B is provided as necessary and need not necessarily be provided.

The display device 100 is a top emission type display device. The second substrate 23 side of the display device 100 is a top side (display surface side), and the first substrate 11 side of the display device 100 is a bottom side. In the following description, in each layer constituting the display device 100, a surface on the top side of the display device 100 is referred to as a first surface, and a surface on the bottom side of the display device 100 is referred to as a second surface.

(Light Emitting Element 24R, 24G, and 24B)

The subpixels 101R, 101G, and 101B include light emitting elements 24R, 24G, and 24B, respectively. The light emitting elements 24R, 24G, and 24B are so-called organic EL elements. The light emitting element 24R is a red light emitting element that emits red light. The light emitting element 24G is a green light emitting element that emits green light. The light emitting element 24B is a blue light emitting element that emits blue light. In the following description, in a case where the light emitting elements 24R, 24G, and 24B are collectively referred to without being particularly distinguished, the light emitting elements 24R, 24G, and 24B are referred to as light emitting elements 24. The light emitting element 24 includes the reflective layer 13, the insulating layer 14, the first electrode 15A, the organic EL layer 17, and the second electrode 18.

(Resonator Structures 25R, 25G, 25B, and 25A)

The light emitting elements 24R, 24G, and 24B have resonator structures 25R, 25G, and 25B, respectively. The resonator structures 25R, 25G, and 25B include the reflective layer 13 and the second electrode 18. The resonator structures 25R, 25G, and 25B resonate and emphasize light of specified wavelengths corresponding to the respective colors of the subpixels 101R, 101G, and 101B, and emit the light toward the display surface. Specifically, the resonator structure 25R resonates and emphasizes red light included in white light generated in the organic EL layer 17, and emits the red light toward the display surface. The resonator structure 25G resonates and emphasizes green light included in white light generated in the organic EL layer 17, and emits the green light toward the display surface. The resonator structure 25B resonates and emphasizes blue light included in white light generated in the organic EL layer 17, and emits the blue light toward the display surface. Note that, in the following description, in a case where the resonator structures 25R, 25G, and 25B are collectively referred to without being particularly distinguished, the resonator structures 25R, 25G, and 25B are referred to as resonator structures 25.

In the display region R1, an optical path length (optical distance) between the reflective layer 13 and the second electrode 18 is set according to light of the specified wavelengths resonated by the resonator structures 25R, 25G, and 25B. More specifically, in the resonator structure 25R, the optical path length between the reflective layer 13 and the second electrode 18 is set so that red light is resonated and emphasized. In the resonator structure 25G, the optical path length between the reflective layer 13 and the second electrode 18 is set so that green light is resonated and emphasized. In the resonator structure 25B, the optical path length between the reflective layer 13 and the second electrode 18 is set so that blue light is resonated and emphasized.

A resonator structure 25R1 is provided in the peripheral region R2. The resonator structure 25R1 includes the reflective layer 13 and the second electrode 18. The resonator structure resonates and emphasizes light of a specified wavelength, and cancels and weakens light of a wavelength other than the specified wavelength. Specifically, the resonator structure 25R1 resonates and emphasizes red light, and cancels and weakens light (for example, blue light) other than red light.

An optical path length (optical distance) between the reflective layer 13 and the second electrode 18 in the peripheral region R2 is set according to light of the specified wavelength resonated by the resonator structure 25R1. More specifically, in the resonator structure 25R1, the optical path length between the reflective layer 13 and the second electrode 18 is set so that red light is resonated and emphasized and light other than the red light is canceled and weakened.

The red light is, for example, light having spectral characteristics with a half-value width in a range of 603 nm or more and 660 nm or less. The green light is, for example, light having spectral characteristics with a half-value width in a range of 515 nm or more and 565 nm or less. The blue light is, for example, light having spectral characteristics with a half-value width in a range of 442 nm or more and 487 nm or less.

(First Substrate 11)

The first substrate 11 is a so-called backplane. The first substrate 11 is provided with a drive circuit that drives the plurality of light emitting elements 24, a power supply circuit that supplies power to the plurality of light emitting elements 24, and the like (none of which are illustrated). A substrate body of the first substrate 11 may include, for example, a semiconductor where a transistor and the like are easily formed or may include glass or resin having low moisture and oxygen permeability. Specifically, the substrate body may be a semiconductor substrate, a glass substrate, a resin substrate, or the like. The semiconductor substrate contains, for example, amorphous silicon, polycrystalline silicon, single crystal silicon, or the like. The glass substrate contains, for example, high strain point glass, soda glass, borosilicate glass, forsterite, lead glass, quartz glass, or the like. The resin substrate contains, for example, at least one selected from the group consisting of polymethyl methacrylate, polyvinyl alcohol, polyvinyl phenol, polyether sulfone, polyimide, polycarbonate, polyethylene terephthalate, polyethylene naphthalate, and the like.

(Insulating Layer 12)

The insulating layer 12 is provided on the first surface of the first substrate 11 and covers the drive circuit, the power supply circuit, and the like. Therefore, the first surface of the first substrate 11 is flattened. The insulating layer 12 insulates between the first substrate 11 and the reflective layer 13. The insulating layer 12 includes a plurality of vias and a plurality of wirings (none of which are illustrated). The plurality of vias electrically connects the reflective layer 13 and the drive circuit.

The insulating layer 12 may have a single layer structure or may have a laminated structure. The insulating layer 12 may be an organic insulating layer, may be an inorganic insulating layer, or may be a laminate thereof. The organic insulating layer contains, for example, at least one selected from the group consisting of a polyimide-based resin, an acrylic resin, a novolac-based resin, and the like. The inorganic insulating layer contains, for example, at least one selected from the group consisting of silicon oxide (SiOₓN_{y}), silicon nitride (SiNₓ), silicon oxynitride (SiOₓN_{y}), and the like.

(Reflective Layer 13)

The reflective layer 13 is provided on the first surface of the insulating layer 12. The reflective layer 13 includes a plurality of reflecting portions 13A, a reflecting portion 13B, and an insulating portion 13C.

The plurality of reflecting portions 13A is provided in the display region R1. Each of the plurality of reflecting portions 13A is provided corresponding to the subpixel 101. The reflecting portions 13A reflect light incident from the organic EL layer 17 through the first electrode 15A and the insulating layer 14. The reflecting portions 13A of the subpixels 101R, 101G, and 101B may have the same thickness. The reflecting portions 13A and the second electrode 18 constitute the resonator structures 25R, 25G, and 25B.

The reflecting portions 13A include a material having light reflectivity. Specifically, the reflective layer 13 contains, for example, at least one metal element selected from the group consisting of silver (Ag), aluminum (Al), platinum (Pt), gold (Au), chromium (Cr), tungsten (W), and the like. The reflective layer 13 may contain the at least one metal element as a constituent element of an alloy. Specific examples of the alloy include a silver alloy and an aluminum alloy.

An underlying layer (not illustrated) may be provided adjacent to the second surface side of the reflecting portions 13A. The underlying layer improves crystal orientation of the reflective layer 13 at a time of film formation of the reflecting portions 13A. The reflecting portions 13A contains, for example, at least one selected from the group consisting of titanium (Ti), titanium nitride (TiN), titanium oxide (TiO₂), and the like.

The reflecting portion 13B is provided in the peripheral region R2. The reflecting portion 13B reflects external light incident on the display device 100 from the display surface side. As illustrated in FIG. 1, the reflecting portion 13B may have a closed loop shape surrounding the display region R1. However, the shape of the reflecting portion 13B is not limited to this, and for example, the reflecting portion 13B may be provided discontinuously in a circumferential direction of the peripheral region R2 or may be provided in a section having a predetermined length in the circumferential direction of the peripheral region R2. The reflecting portion 13B may be a wiring layer or the like including copper (Cu) wiring or the like. The reflecting portion 13B and the second electrode 18 constitute the resonator structure 25R1.

The reflecting portion 13B includes a material having light reflectivity. The reflecting portion 13B may contain a similar material to the reflecting portions 13A.

The insulating portion 13C is provided between adjacent reflecting portions 13A and insulates the adjacent reflecting portions 13A from each other. Furthermore, the insulating portion 13C is provided between adjacent reflecting portions 13A and 13B and insulates the adjacent reflecting portions 13A and 13B from each other. As a constituent material of the insulating portion 13C, a material similar to that of the insulating layer 12 can be exemplified.

(Insulating Layer 14)

The insulating layer 14 is provided on the first surface of the reflective layer 13. The insulating layer 14 insulates the reflective layer 13 from the plurality of first electrodes 15A. Furthermore, the insulating layer 14 also has a function as an optical path length adjustment layer that adjusts the optical path length between the reflective layer 13 and the second electrode 18 for each of the subpixels 101R, 101G, and 101B of the three colors. The insulating layer 14 has transparency.

A height of the first surface of the insulating layer 14 in the display region R1 varies among the subpixels 101R, 101G, and 101B of the three colors. The thickness of the insulating layer 14 in the display region R1 varies among the subpixels 101R, 101G, and 101B of the three colors. The thicknesses of the insulating layer 14 for the subpixels 101R, 101G, and 101B of the three colors are set so that light corresponding to the respective colors of the subpixels 101R, 101G, and 101B is resonated by the resonator structures 25R, 25G, and 25B. That is, the thickness of the insulating layer 14 of the subpixel 101R is set so that red light corresponding to the color of the subpixel 101R is resonated and emphasized by the resonator structure 25R. The thickness of the insulating layer 14 of the subpixel 101G is set so that green light corresponding to the color of the subpixel 101G is resonated and emphasized by the resonator structure 25G. The thickness of the insulating layer 14 of the subpixel 101B is set so that blue light corresponding to the color of the subpixel 101B is resonated and emphasized by the resonator structure 25B.

The thickness of the insulating layer 14 in the peripheral region R2 may be the same as the thickness of the insulating layer 14 of the subpixel 101R among the subpixels 101R, 101G, and 101B. The thickness of the insulating layer 14 in the peripheral region R2 is set so that red light is resonated and emphasized by the resonator structure 25R1 and light other than the red light is canceled and weakened.

The insulating layer 14 includes a plurality of vias (connection portions) 14A and a plurality of vias (connection portions) 14B. The plurality of vias 14A is provided in the display region R1. One via 14A is provided for one subpixel 101. The via 14A electrically connects the reflecting portion 13A and the first electrode 15A. From the viewpoint of suppressing decrease in performance of the resonator structure the via 14A is preferably provided so as not to overlap an opening 16A of the insulating layer 16 in a thickness direction of the display device 100.

The plurality of vias 14B is provided in the peripheral region R2. The plurality of vias 14B electrically connects the reflecting portion 13B and the third electrode 15B. From the viewpoint of suppressing decrease in performance of the resonator structure 25, the via 14B is preferably provided so as not to overlap the opening 16A of the insulating layer 16 in a thickness direction of the display device 100.

As a constituent material of the insulating layer 14, a material similar to that of the insulating layer 12 can be exemplified.

(First Electrode 15A)

The plurality of first electrodes 15A is provided on the first surface of the insulating layer 14 in the display region R1. Each of the plurality of first electrodes 15A is provided corresponding to the subpixel 101. The first electrode 15A is an anode. When a voltage is applied between the first electrode 15A and the second electrode 18, holes are injected from the first electrode 15A into the organic EL layer 17. The first electrode 15A is electrically connected to the reflecting portion 13A by the via 14A.

From the viewpoint of increasing light emission efficiency, the first electrode 15A preferably includes a material having a high work function and a high transmittance. The first electrode 15A is a transparent electrode having transparency to light generated in the organic EL layer 17. The transparent electrode contains, for example, a transparent conductive oxide (TCO). The transparent conductive oxide includes, for example, at least one selected from the group consisting of a transparent conductive oxide containing indium (hereinafter referred to as “indium-based transparent conductive oxide”), a transparent conductive oxide containing tin (hereinafter referred to as a “tin-based transparent conductive oxide”), and a transparent conductive oxide containing zinc (hereinafter referred to as a “zinc-based transparent conductive oxide”).

The indium-based transparent conductive oxide contains, for example, indium tin oxide (ITO), indium zinc oxide (IZO), indium gallium oxide (IGO), indium gallium zinc oxide (IGZO), or fluorine-doped indium oxide (IFO). Among these transparent conductive oxides, indium tin oxide (ITO) is particularly preferable. This is because indium tin oxide (ITO) has a particularly low barrier for hole injection into the organic EL layer 17 in terms of a work function and therefore a drive voltage of the display device 100 can be particularly reduced. The tin-based transparent conductive oxide contains, for example, tin oxide, antimony-doped tin oxide (ATO), or fluorine-doped tin oxide (FTO). The zinc-based transparent conductive oxide contains, for example, zinc oxide, aluminum-doped zinc oxide (AZO), boron-doped zinc oxide, or gallium-doped zinc oxide (GZO).

(Second Electrode 18)

The second electrode 18 is provided on the first surface of the organic EL layer 17 and the first surface of the third electrode 15B. The second electrode 18 is continuously provided from the display region R1 to the peripheral region R2, and is provided as an electrode common to all the subpixels 101 in the display region R1. The second electrode 18 is a cathode. The second electrode 18 is a transparent electrode having transparency to light generated in the organic EL layer 17. Here, the transparent electrode also encompasses a semi-transmissive reflective layer. From the viewpoint of increasing light emission efficiency, the second electrode 18 preferably includes a material having a low work function.

The second electrode 18 includes, for example, at least one of a metal layer or a metal oxide layer. More specifically, the second electrode 18 is a single-layer film of a metal layer or a metal oxide layer or a laminated film of a metal layer and a metal oxide layer. In a case where the second electrode 18 is a laminated film, the metal layer may be provided on the organic EL layer 17 side or the metal oxide layer may be provided on the organic EL layer 17 side, but from the viewpoint of providing a layer having a low work function adjacent to the organic EL layer 17, the metal layer is preferably provided on the organic EL layer 17 side.

The metal layer contains, for example, at least one metal element selected from the group consisting of magnesium (Mg), aluminum (Al), silver (Ag), calcium (Ca), sodium (Na), and the like. The metal layer may contain the at least one metal element as a constituent element of an alloy. Specific examples of the alloy include an MgAg alloy, an MgAl alloy, an AlLi alloy, and the like. As the metal oxide, a transparent conductive oxide similar to that of the first electrode 15A can be exemplified.

The second electrode 18 may be a multilayer film in which a first metal layer and a second metal layer are laminated. Of the first metal layer and the second metal layer, the first metal layer may be provided on the organic EL layer 17 side.

The first metal layer contains, for example, at least one selected from the group consisting of calcium (Ca), barium (Ba), lithium (Li), cesium (Cs), indium (In), magnesium (Mg), and silver (Ag). The first metal layer may contain the at least one metal element as a constituent element of an alloy. The second metal layer contains, for example, at least one selected from the group consisting of magnesium (Mg) and silver (Ag). The second metal layer may contain the at least one metal element as a constituent element of an alloy.

(Third Electrode 15B)

The third electrode 15B is provided on the first surface of the insulating layer 14 in the peripheral region R2. The third electrode 15B is preferably a transparent electrode. The transparent electrode is preferably a transparent electrode having the same configuration as the first electrode 15A. Specifically, the transparent electrode is preferably a transparent electrode having the same thickness as the first electrode 15A and includes the same material as the first electrode 15A. In this case, the third electrode 15B can be formed in the same step as the first electrode 15A. The third electrode 15B has a shape similar to that of the reflecting portion 13B. The third electrode 15B has, for example, a closed loop shape surrounding the display region R1.

(Insulating Layer 16)

The insulating layer 16 is provided on the first surface of the insulating layer 14 and between adjacent first electrodes 15A. The insulating layer 16 insulates the adjacent first electrodes 15A from each other. Furthermore, the insulating layer 16 insulates the adjacent first electrode 15A and third electrode 15B from each other.

The insulating layer 16 has a plurality of openings 16A and an opening 16B. Each of the plurality of openings 16A is provided corresponding to the subpixel 101. More specifically, each of the plurality of openings 16A is provided on the first surface (surface on the organic EL layer 17 side) of a corresponding one of the first electrodes 15A. The first electrode 15A and the organic EL layer 17 are in contact with each other through the opening 16A. The opening 16B is provided on the first surface (surface on the second electrode 18 side) of the third electrode 15B. The opening 16B may have a shape similar to that of the third electrode 15B. The third electrode 15B and the second electrode 18 are electrically in contact with each other through the opening 16B.

As a constituent material of the insulating layer 16, a material similar to that of the insulating layer 12 can be exemplified.

(Organic EL Layer 17)

The organic EL layer 17 is provided between the first electrode 15A and the second electrode 18. The organic EL layer 17 is continuously provided over all the subpixels 101 in the display region R1, and is provided as an organic layer common to all the subpixels 101 in the display region R1.

The organic EL layer 17 is configured to be able to emit white light. The organic EL layer 17 may be a 1-stack organic EL layer including a single-layer light emitting unit, may be a 2-stack organic EL layer including a two-layer light emitting unit, or may be any of other organic EL layers. The 1-stack organic EL layer has, for example, a configuration in which a hole injection layer, a hole transport layer, a red light emitting layer, a light emission separation layer, a blue light emitting layer, a green light emitting layer, an electron transport layer, and an electron injection layer are laminated in this order from the first electrode 15A toward the second electrode 18. The 2-stack organic EL layer has, for example, a configuration in which a hole injection layer, a hole transport layer, a blue light emitting layer, an electron transport layer, a charge generation layer, a hole transport layer, a yellow light emitting layer, an electron transport layer, and an electron injection layer are laminated in this order from the first electrode 15A toward the second electrode 18.

The hole injection layer is for increasing efficiency of hole injection into each light emitting layer and suppressing leakage. The hole transport layer is for increasing efficiency of hole transport to each light emitting layer. The electron injection layer is for increasing efficiency of electron injection into each light emitting layer. The electron transport layer is for increasing efficiency of electron transport to each light emitting layer. The light emission separation layer is a layer for adjusting injection of carriers into each light emitting layer, and light emission balance of the colors is adjusted by injecting electrons or holes into each light emitting layer via the light emission separation layer. The charge generation layer supplies electrons and holes to two light emitting layers sandwiching the charge generation layer, respectively.

The red light emitting layer, the green light emitting layer, the blue light emitting layer, and the yellow light emitting layer generate red light, green light, blue light, and yellow light, respectively as a result of recombination of holes injected from the first electrode 15A and electrons injected from the second electrode 18 upon application of an electric field.

(Protective Layer 19)

The protective layer 19 is provided on the first surface of the second electrode 18 and covers the plurality of light emitting elements 24. The protective layer 19 shields the light emitting elements 24 from outside air, and suppresses moisture infiltration into the light emitting elements 24 from an external environment. Furthermore, in a case where the second electrode 18 includes a metal layer, the protective layer 19 may have a function of suppressing oxidation of the metal layer. The protective layer 19 has transparency.

The protective layer 19 contains, for example, an inorganic material or a polymer resin having low hygroscopicity. The protective layer 19 may have a single-layer structure or may be a multilayer structure. In a case where a thickness of the protective layer 19 is made large, the protective layer 19 preferably has a multilayer structure. This is to alleviate internal stress in the protective layer 19. The inorganic material contains, for example, at least one selected from the group consisting of silicon oxide (SiOₓ), silicon nitride (SiNₓ), silicon oxynitride (SiOₓN_{y}), titanium oxide (TiOₓ), aluminum oxide (AlOₓ), and the like. The polymer resin contains, for example, at least one selected from the group consisting of a thermosetting resin, an ultraviolet curable resin, and the like.

(Flattening Layer 20)

The flattening layer 20 is provided on the first surface of the protective layer 19 and flattens the first surface of the protective layer 19. The flattening layer 20 contains, for example, a polymer resin. The polymer resin contains, for example, at least one selected from the group consisting of a thermosetting resin, an ultraviolet curable resin, and the like. The flattening layer 20 has transparency.

(Color Filter 21)

The color filter 21 is provided on the first surface of the flattening layer 20. The color filter 21 is, for example, an on-chip color filter (OCCF). The color filter 21 includes a plurality of red filters 21R, a plurality of green filters 21G, and a plurality of blue filters 21B. The plurality of red filters 21R, the plurality of green filters 21G, and the plurality of blue filters 21B are provided in the display region R1. The red filter 21R, the green filter 21G, and the blue filter 21B are provided so as to overlap the light emitting elements 24R, 24G, and 24B in the thickness direction of the display device 100, respectively. The red filter 21R and the light emitting element 24R constitute the subpixel 101R, the green filter 21G and the light emitting element 24G constitute the subpixel 101G, and the blue filter 21B and the light emitting element 24B constitute the subpixel 101B.

Red light, green light, and blue light emitted from the light emitting element 24R, the light emitting element 24G, and the light emitting element 24B pass through the red filter 21R, the green filter 21G, and the blue filter 21B, respectively. Therefore, red light, green light, and blue light having high color purity are emitted from the display surface. Furthermore, a light shielding layer (not illustrated) may be provided in a region between the filters 21R, 21G, and 21B of the colors, that is, between the subpixels 101 of the color filter 21.

The color filter 21 further includes a blue filter (filter of a predetermined color) 21B1 as a single-layer filter. The blue filter 21B1 has the same color as a filter included in one of the subpixels 101R, 101G, and 101B. The blue filter 21B1 is provided in the peripheral region R2. Note that the color filter 21 is not limited to the on-chip color filter, and may be provided on the second surface of the second substrate 23. The light resonated by the resonator structure 25R1 is light (red light) of a color different from the color of the blue filter 21B1. Therefore, in the resonator structure 25R1, light (blue light) of the same color as the color of the blue filter 21B1 is weakened. That is, in the resonator structure 25R1, the blue light that has passed through the blue filter 21B1 is weakened. The blue filter 21B1 and the resonator structure 25R1 block light of a visible light region. In the present specification, the “visible light region” refers to a wavelength region of 380 nm or more and 780 nm or less.

(Filling Resin Layer 22)

The filling resin layer 22 is provided between the color filter 21 and the second substrate 23. The filling resin layer 22 has a function as an adhesive layer for joining the color filter 21 and the second substrate 23. The filling resin layer 22 has transparency. The filling resin layer 22 contains, for example, at least one selected from the group consisting of a thermosetting resin, an ultraviolet curable resin, and the like.

(Second Substrate 23)

The second substrate 23 is provided so as to face the first substrate 11. The second substrate 23 seals the light emitting elements 24, the color filter 21, and the like. The second substrate 23 has transparency. The second substrate 23 includes a material such as glass transparent to each color light emitted from the color filter 21.

[Method for Manufacturing Display Device]

An example of a method for manufacturing the display device 100 according to the first embodiment of the present disclosure will be described below.

First, a drive circuit, a power supply circuit, and the like are formed on the first surface of the substrate body by using, for example, a thin film forming technique, a photolithography technique, an etching technique, and the like. As a result, the first substrate 11 is obtained. Next, the insulating layer 12 is formed on the first surface of the first substrate 11 so as to cover the drive circuit, the power supply circuit, and the like, for example, by a chemical vapor deposition (CVD) method. Next, a metal layer is formed on the first surface of the insulating layer 12, for example, by a sputtering method. Next, the metal layer is patterned by using, for example, a photolithography technique and an etching technique to form the plurality of reflecting portions 13A and the reflecting portion 13B.

Next, an insulating layer is formed on the first surface of the insulating layer 12 so as to cover the plurality of reflecting portions 13A and the reflecting portion 13B, for example, by a CVD method. Next, an unnecessary insulating layer is removed by polishing the first surface of the insulating layer, for example, by a chemical mechanical polishing (CMP) method, and the first surfaces of the plurality of reflecting portions 13A and the reflecting portion 13B are exposed. As a result, the reflective layer 13 is formed. Next, the insulating layer 14 having different thicknesses among the subpixels 101R, 101G, and 101B is formed by using, for example, a CVD method, a photolithography technique, an etching technique, or the like. In this process, the thickness of the insulating layer 14 in the peripheral region R2 is set to be the same as the thickness of the insulating layer 14 in the subpixel 101R. Next, the plurality of vias 14A and the plurality of vias 14B are formed in the insulating layer 14 by using, for example, a CVD method, a photolithography technique, an etching technique, or the like.

Next, a metal oxide layer is formed on the first surface of the insulating layer 14, for example, by a sputtering method, and then the metal oxide layer is patterned by using, for example, a photolithography technique and an etching technique. As a result, the plurality of first electrodes 15A and the third electrode 15B are formed.

Next, the insulating layer 16 is formed on the first surface of the insulating layer 14 so as to cover the plurality of first electrodes 15A and the third electrode 15B, for example, by a plasma CVD method. Next, the opening 16A is formed above the first surface of each of the plurality of first electrodes 15A and the opening 16B is formed above the first surface of the third electrode 15B, for example, by a photolithography technique and a dry etching technique.

Next, the organic EL layer 17 is formed in the display region R1 by laminating the hole injection layer, the hole transport layer, the red light emitting layer, the light emission separation layer, the blue light emitting layer, the green light emitting layer, the electron transport layer, and the electron injection layer in this order on the first surfaces of the first electrodes 15A and the first surface of the insulating layer 16, for example, by a vapor deposition method. Next, the second electrode 18 is formed from the display region R1 to the peripheral region R2, for example, by a vapor deposition method or a sputtering method. As a result, the plurality of light emitting elements 24 is formed on the first surface of the insulating layer 12.

Next, the protective layer 19 is formed on the first surface of the second electrode 18, for example, by a CVD method or a vapor deposition method, and then the flattening layer 20 is formed on the first surface of the protective layer 19, for example, by a spin coating method. Next, the color filter 21 is formed on the first surface of the flattening layer 20, for example, by photolithography. The blue filter 21B in the display region R1 and the blue filter 21B1 in the peripheral region R2 are manufactured in the same process.

Next, the color filter 21 is covered with the filling resin layer 22 by using, for example, a one drop fill (ODF) method, and then the second substrate 23 is placed on the filling resin layer 22. Next, the first substrate 11 and the second substrate 23 are bonded with the filling resin layer 22 interposed therebetween, for example, by applying heat to the filling resin layer 22 or irradiating the filling resin layer 22 with ultraviolet rays to cure the filling resin layer 22. As a result, the display device 100 is sealed. In this way, the display device 100 illustrated in FIG. 2 is obtained.

[Operation and Effect]

As described above, the display device 100 according to the first embodiment includes the reflecting portion 13B, the insulating layer 14, the second electrode 18, and the blue filter 21B in this order in the peripheral region R2 around the display region R1. The reflecting portion 13B and the second electrode 18 constitute the resonator structure 25R, and the resonator structure 25R resonates red light different from the color of the blue filter 21B.

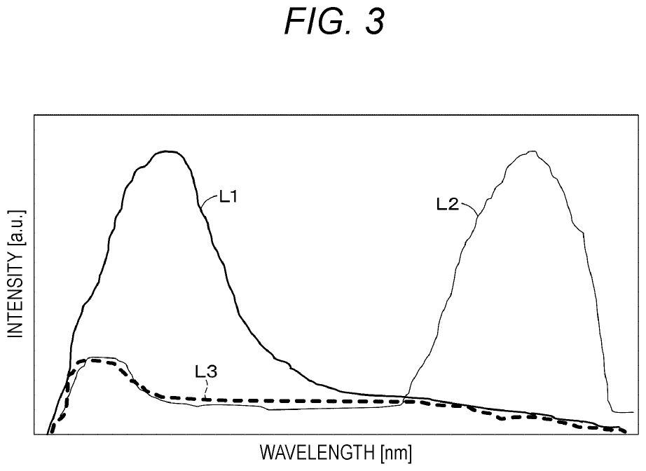

The blue filter 21B has a spectral transmission characteristic that transmits blue light among light of the visible light region and blocks light other than blue light (see “spectral curve L1” in FIG. 3). On the other hand, the resonator structure 25R has a function of resonating and emphasizing red light among light of the visible light region and canceling and weakening light other than the red light (see “spectral curve L2” in FIG. 3). Therefore, since the single-layer blue filter 21B and the resonator structure 25R are provided in the peripheral region R2, it is possible to block light of the visible light region (see “spectral curve L3” in FIG. 3). Therefore, reflection of external light in the peripheral region R2 can be suppressed. Note that, in FIG. 3, “INTENSITY” on the vertical axis indicates an intensity of light that has passed through the blue filter 21B for “spectral curve L1”, indicates an intensity of light emitted from the resonator structure 25R for “spectral curve L2”, and indicates an intensity of reflected light in the peripheral region R2 for “spectral curve L3”.

In the display device 100 according to the first embodiment, since the filter provided in the peripheral region R2 is the single-layer blue filter 21B, a step can be made less likely to be generated between the peripheral region R2 and the display region R1. Therefore, even if a width of the peripheral region R2 is narrowed, it is possible to suppress occurrence of non-uniformity in the thickness of the color filter 21 in the vicinity of an inner side of the peripheral region R2 in the process of manufacturing the color filter 21. Therefore, image quality degradation (unevenness) in the vicinity of the inner side of the peripheral region R2 can be suppressed. Therefore, even in a case where the frame of the display device 100 is narrowed, good image quality can be assured.

On the other hand, in a case where a filter provided in a peripheral edge region to suppress reflection is a laminated body in which two or more layers of color filters are laminated, a step is likely to be generated between the peripheral region and the display region. Therefore, in a case where the width of the peripheral edge region is narrowed, non-uniformity is likely to occur in the thickness of the color filter in the vicinity of the inner side of the peripheral region in the process of manufacturing the color filter, and thereby image quality deterioration (unevenness) is likely to occur in the vicinity of the inner side of the peripheral region. Therefore, in a case where the frame of the display device 100 is narrowed, it is difficult to assure good image quality.

In the display device 100 according to the first embodiment, it is possible to manufacture the resonator structure 25R1 in the peripheral region R2 simultaneously with manufacturing of the resonator structure 25R in the display region R1. Furthermore, the blue filter 21B1 in the peripheral region R2 can be manufactured simultaneously with manufacturing of the blue filter 21B in the display region R1. Therefore, the display device 100 can be manufactured while suppressing an increase in manufacturing steps.

### 2 Second Embodiment

[Configuration of Display Device]

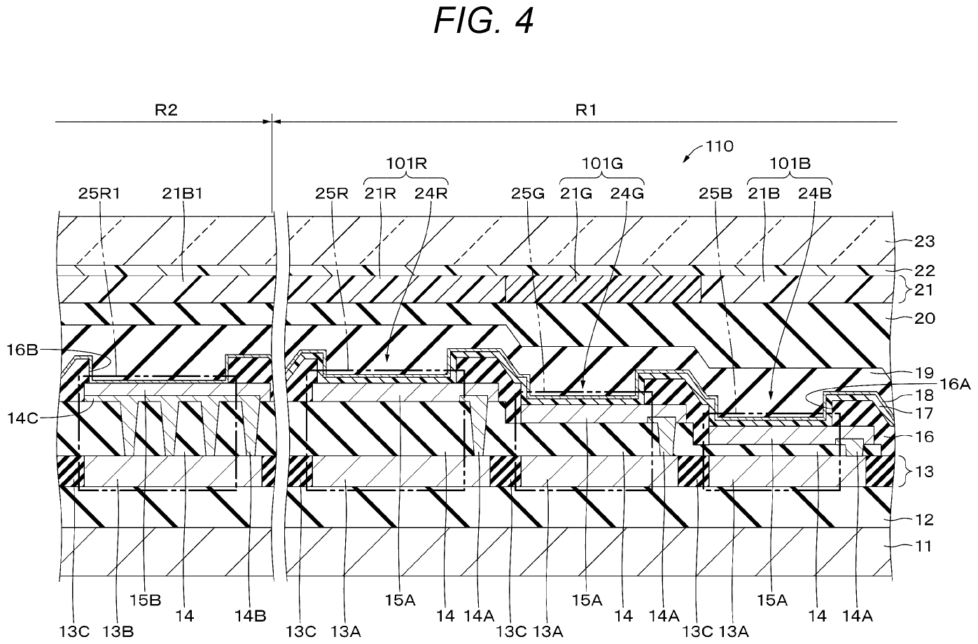

FIG. 4 is a cross-sectional view illustrating a configuration example of a display device 110 according to a second embodiment of the present disclosure. The display device 110 is different from the display device 100 according to the first embodiment in that the display device 110 includes a light absorption layer 14C between an insulating layer 14 and a third electrode 15B. Note that, in the second embodiment, portions similar to those of the first embodiment are given same reference signs, and description thereof will be omitted.

The light absorption layer 14C is provided at a position overlapping a blue filter 21B1 in a thickness direction of the display device 100. The light absorption layer 14C has electric conductivity. The light absorption layer 14C is an example of a light absorption portion, and is configured to be able to absorb blue light that has passed through the blue filter 21B1. The blue filter 21B and the light absorption layer 14C block external light incident on the display device 110 from a display surface of a peripheral region R2.

The light absorption layer 14C and a reflecting portion 13B are electrically connected by a plurality of vias 14B. At least one of the plurality of vias 14B is provided at a position overlapping an opening 16A of an insulating layer 16 in the thickness direction of the display device 110. The plurality of vias 14B may include the same material as that of the light absorption layer 14C and may be integral with the light absorption layer 14C.

The light absorption layer 14C contains, for example, an inorganic material having light absorbency. The inorganic material includes, for example, a metal nitride. The metal nitride includes, for example, at least one selected from the group consisting of titanium nitride (TiNₓ), tantalum nitride (TaNₓ), and the like.

Although the example in which the resonator structure R1 that resonates and emphasizes red light and cancels and weakens light other than the red light is constituted by the reflecting portion 13B and the second electrode 18 has been described in the first embodiment, the resonator structure 25R1 may be constituted by the reflecting portion 13B and the second electrode 18 or need not be constituted by the reflecting portion 13B and the second electrode 18 in the second embodiment. In a case where the resonator structure 25R1 is constituted, blue light can be reduced in both the light absorption layer 14C and the resonator structure 25R1.

[Operation and Effect]

As described above, the display device 110 according to the second embodiment includes the reflecting portion 13B, the light absorption layer 14C, the second electrode 18, and the blue filter 21B in this order in the peripheral region R2 around a display region R1. The blue filter 21B transmits blue light included in external light incident on the peripheral region R2 and absorbs light other than blue light. The light absorption layer 14C absorbs the blue light that has passed through the blue filter 21B. Therefore, the blue filter 21B and the light absorption layer 14C can block external light incident on the peripheral region R2. Therefore, reflection of external light in the peripheral region R2 can be suppressed.

### 3 Third Embodiment

[Configuration of Display Device]

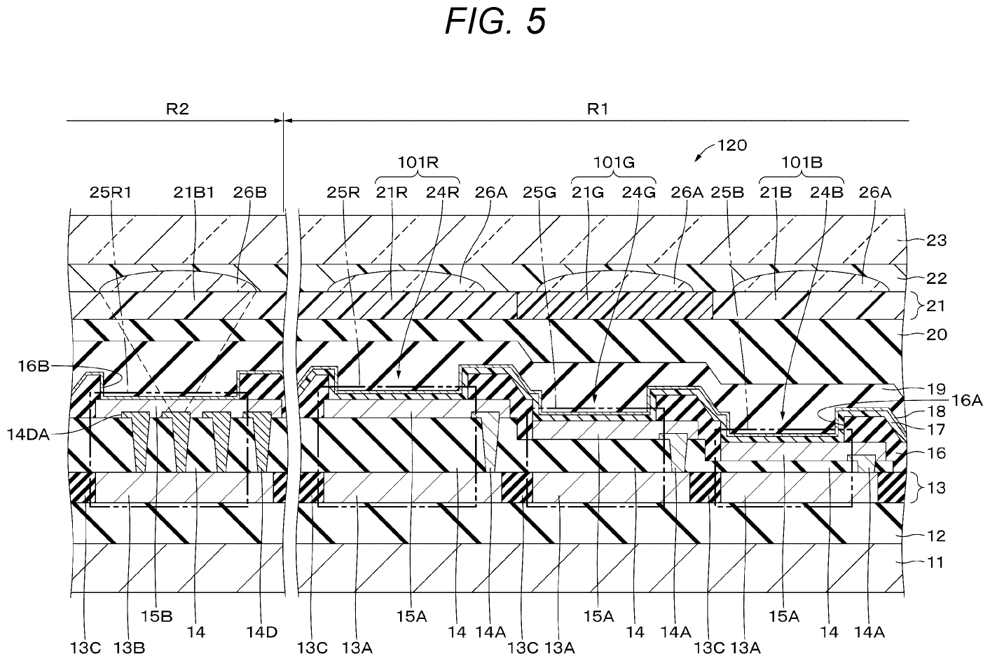

FIG. 5 is a cross-sectional view illustrating a configuration example of a display device 120 according to a third embodiment of the present disclosure. The display device 120 is different from the display device 100 according to the first embodiment in that the display device 120 includes a plurality of lenses 26A and a plurality of lenses 26B and includes a plurality of vias 14D having light absorbency instead of the plurality of vias 14B (see FIG. 2). Note that, in the third embodiment, portions similar to those of the first embodiment are given same reference signs, and description thereof will be omitted.

The plurality of vias 14D is provided in the peripheral region R2. Similarly to the via 14B, the plurality of vias 14D connects a reflecting portion 13B and a third electrode 15B. The plurality of vias 14D is an example of a light absorption portion, and is configured to be able to absorb blue light that has passed through the blue filter 21B1. At least one of the plurality of vias 14D is provided at a position overlapping an opening 16A of an insulating layer 16 in a thickness direction of the display device 120. The plurality of vias 14D contains a similar material to the light absorption layer 14C according to the second embodiment.

The plurality of lenses 26A is provided on a first surface of a color filter 21 in a display region R1. Each of the plurality of lenses 26A is provided on a red filter 21R, a green filter 21G, and a blue filter 21B. The plurality of lenses 26A is covered with a filling resin layer 22.

The lens 26A on the red filter 21R collects red light emitted from the red filter 21R toward a front of the display device 100. The lens 26A on the green filter 21G collects green light emitted from the green filter 21G toward the front of the display device 100. The lens 26A on the blue filter 21B collects blue light emitted from the blue filter 21B toward the front of the display device 100. Since the plurality of lenses 26A is provided on the first surface of the color filter 21 in the display region R1 as described above, light utilization efficiency in a front direction is increased. The lenses 26B have, for example, a dome shape, a truncated cone shape, or the like.

The plurality of lenses 26B is provided on the first surface of the color filter 21 in the peripheral region R2, specifically, on a first surface of a blue filter 21B1. The plurality of lenses 26B is, for example, arranged in one row or two rows along an outer periphery of the display region R1. The plurality of lenses 26B is covered with the filling resin layer 22. The plurality of lenses 26B collects external light incident on a display surface of the peripheral region R2 onto end portions 14DA of the vias 14D. The lenses 26B have, for example, a dome shape, a truncated cone shape, or the like.

The lenses 26B may have the same shape as the lenses 26A or may have a shape different from the lenses 26A. The lenses 26B may be columnar lenses (for example, cylindrical lenses) extending along the outer periphery of the display region R1.

Although the example in which the resonator structure 25R1 that resonates and emphasizes red light and cancels and weakens light other than the red light is constituted by the reflecting portion 13B and the second electrode 18 has been described in the first embodiment, the resonator structure 25R1 may be constituted by the reflecting portion 13B and the second electrode 18 or need not be constituted by the reflecting portion 13B and the second electrode 18 in the second embodiment. In a case where the resonator structure 25R1 is constituted, blue light can be reduced in both the plurality of vias 14D and the resonator structure 25R1.

[Operation and Effect]

As described above, in the display device 120 according to the third embodiment, an insulating layer 14 includes the vias 14D, which are light absorption portions, and the lenses 26B collect light incident on the blue filter 21B1 onto the end portions 14DA of the vias 14B. Light other than blue light included in external light incident on the peripheral region R2 is absorbed by the blue filter 21B1. The blue light that has passed through the blue filter 21B1 is collected onto and absorbed by the end portions 14DA of the vias 14D. Therefore, the blue filter 21B1 and the plurality of vias 14D can block external light incident on the peripheral region R2. Therefore, reflection of external light in the peripheral region R2 can be suppressed.

<4 Modifications>

[Modification 1]

Although an example in which the display device 100 includes the blue filter 21B1 as a filter of a predetermined color in the peripheral region R2 has been described in the first embodiment, the display device 100 may include a red filter 21R or a green filter 21G as a filter of a predetermined color in the peripheral region R2 instead of the blue filter 21B1.

In a case where the display device 100 includes the red filter 21R in the peripheral region R2, a resonator structure 25B that resonates and emphasizes blue light and cancels and weakens light other than blue light is provided instead of the resonator structure 25R1. Since the red filter 21R and the resonator structure 25B are provided in the peripheral region R2, external light incident on the peripheral region R2 can be blocked. Therefore, a similar effect to the first embodiment can be obtained. A thickness of the insulating layer 14 in the peripheral region R2 may be set to the same thickness as the insulating layer 14 in a blue subpixel 101B.

Also in the second or third embodiment, a similar configuration to that of the modification of the first embodiment may be used.

[Modification 2]

Although an example in which the display device 110 includes the blue filter 21B1 in the peripheral region R2 has been described in the second embodiment, the display device 110 may include a red filter 21R or a green filter 21G in the peripheral region R2 instead of the blue filter 21B1.

In a case where the display device 110 includes the red filter 21R in the peripheral region R2, a light absorption layer capable of absorbing red light is used as the light absorption layer 14C. Since the red filter 21R and the light absorption layer 14C are provided in the peripheral region R2, external light incident on the peripheral region R2 can be blocked. Therefore, a similar effect to the second embodiment can be obtained.

In a case where the display device 110 includes the green filter 21G in the peripheral region R2, a light absorption layer capable of absorbing green light is used as the light absorption layer 14C. Since the green filter 21G and the light absorption layer 14C are provided in the peripheral region R2, external light incident on the peripheral region R2 can be blocked. Therefore, a similar effect to the second embodiment can be obtained.

[Modification 3]

Although an example in which the display device 120 includes the blue filter 21B1 in the peripheral region R2 has been described in the third embodiment, the display device 120 may include a red filter 21R or a green filter 21G in the peripheral region R2 instead of the blue filter 21B1.

In a case where the display device 120 includes the red filter 21R in the peripheral region R2, vias capable of absorbing red light are used as the vias 14D. Since the red filter 21R and the vias 14D are provided in the peripheral region R2, external light incident on the peripheral region R2 can be blocked. Therefore, a similar effect to the third embodiment can be obtained.

In a case where the display device 120 includes the green filter 21G in the peripheral region R2, vias capable of absorbing green light are used as the vias 14D. Since the green filter 21G and the vias 14D are provided in the peripheral region R2, external light incident on the peripheral region R2 can be blocked. Therefore, a similar effect to the third embodiment can be obtained.

[Modification 4]

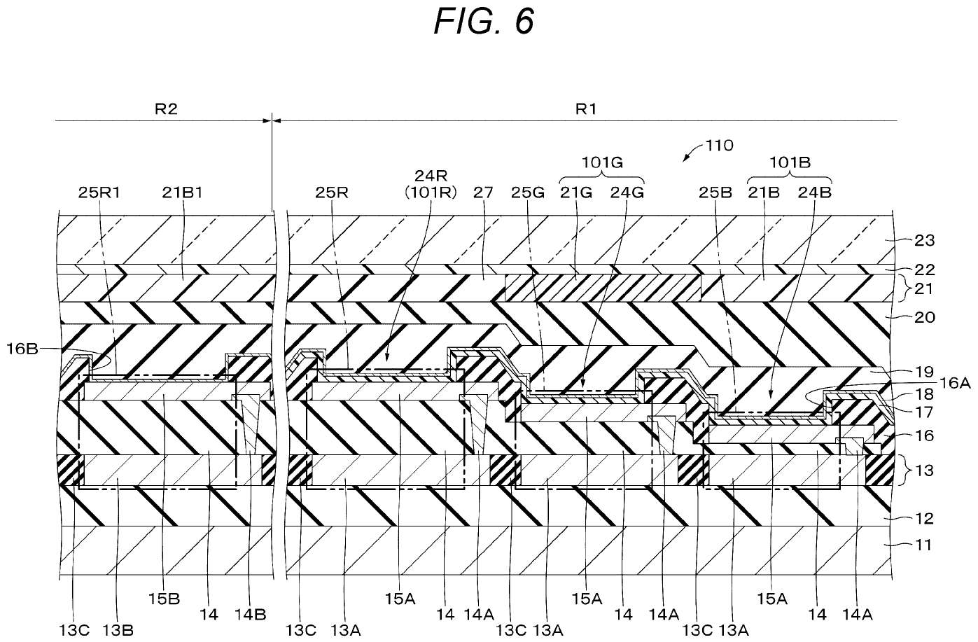

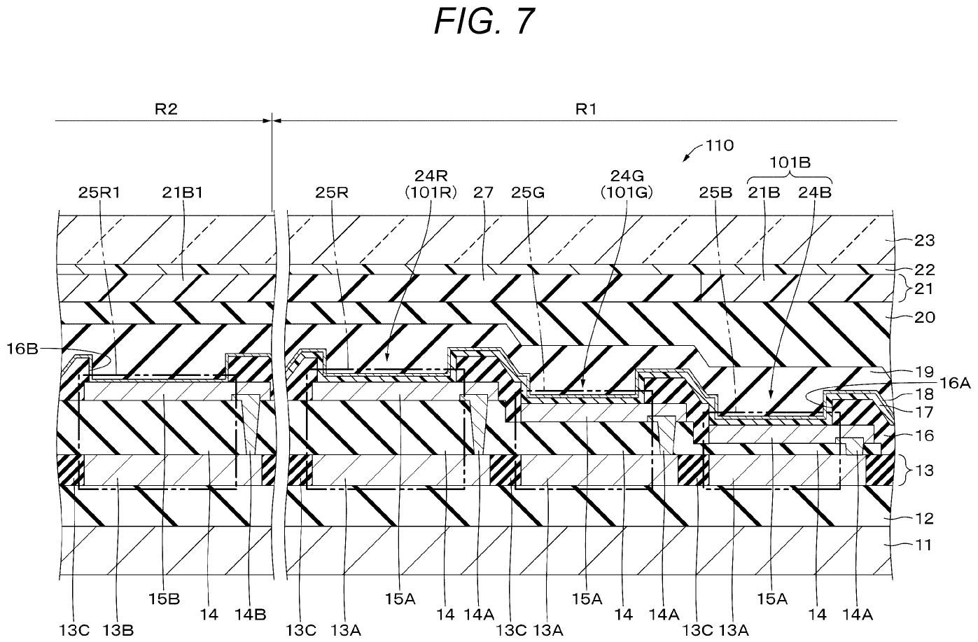

Although an example in which the color filter 21 includes filters of three colors, that is, the red filter 21R, the green filter 21G, and the blue filter 21B has been described in the first to third embodiments, the color filter 21 may include filters of two colors as illustrated in FIG. 6 or may include a filter of one color as illustrated in FIG. 7. Alternatively, the display devices 100, 110, and 120 may include no color filter 21.

In a case where the color filter 21 includes a filter of one color or filters of two colors, the flattening layer 27 may be provided in a filter missing portion as illustrated in FIGS. 6 and 7 in order to suppress occurrence of unevenness caused by the filter missing portion.

In the subpixel 101 in which no filter is provided, light of a predetermined color is extracted by the resonator structure 25. On the other hand, in the subpixel 101 in which a filter is provided, light of a predetermined color is extracted by a combination of the filter and the resonator structure 25. From the viewpoint of improving color purity, it is preferable to combine the filter and the resonator structure 25.

[Modification 5]

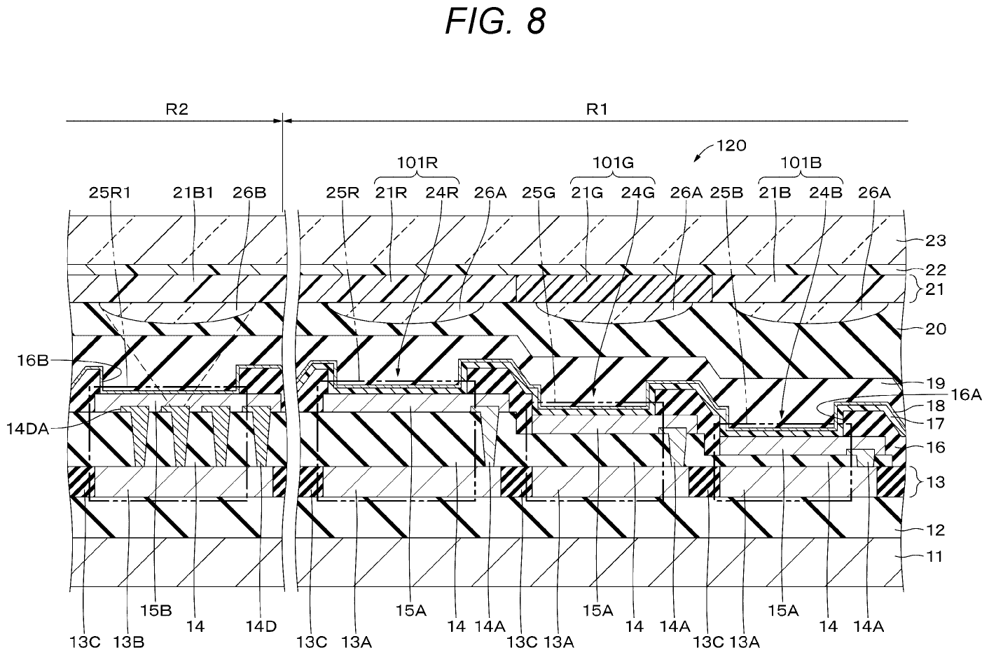

Although an example in which the plurality of lenses 26A and the plurality of lenses 26B are provided on the first surface of the color filter 21 (see FIG. 5) has been described in the third embodiment, the plurality of lenses 26A and the plurality of lenses 26B may be provided on the second surface of the color filter 21 as illustrated in FIG. 8.

[Modification 6]

Although an example in which the optical path length between the reflecting portion 13A and the second electrode 18 in the display region R1 is adjusted by the thickness of the insulating layer 14 has been described in the first to third embodiments, the optical path length may be adjusted by the thickness of the reflecting portion 13A or the first electrode 15A or may be adjusted by the thicknesses of two or more types among the insulating layer 14, the reflecting portion 13A, and the first electrode 15A.

Furthermore, although an example in which the optical path length between the reflecting portion 13B and the second electrode 18 in the peripheral region R2 is adjusted by the thickness of the insulating layer 14 has been described in the first to third embodiments, the optical path length may be adjusted by the thickness of the reflecting portion 13B or the third electrode 15B or may be adjusted by the thicknesses of two or more types among the insulating layer 14, the reflecting portion 13B, and the third electrode 15B.

### 5 Application Example

(Electronic Apparatus)

The display devices 100, 110, and 120 (hereinafter referred to as the “display device 100 and the like”) according to the first to third embodiments and modifications thereof may be provided in various electronic apparatuses. In particular, the display device 100 and the like are preferably provided in electronic apparatuses that require high resolution and are used in an enlarged manner close to eyes such as an electronic viewfinder of a video camera or a single-lens reflex camera and a head-mounted display.

### Specific Example 1

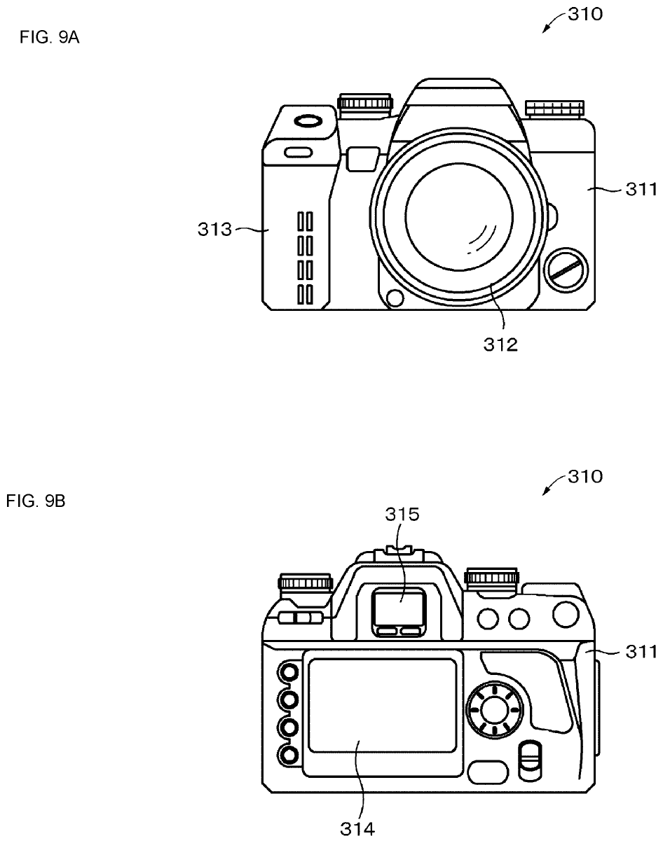

FIG. 9A is a front view illustrating an example of an external appearance of a digital still camera 310. FIG. 9B is a back view illustrating an example of an external appearance of the digital still camera 310. The digital still camera 310 is of a lens interchangeable single lens reflex type, and includes an interchangeable imaging lens unit (interchangeable lens) 312 at a substantially center on a front face of a camera body portion (camera body) 311 and a grip portion 313 to be held by a photographer on a left side on the front face.

A monitor 314 is provided at a position shifted to a left side from a center of a back face of the camera body portion 311. An electronic viewfinder (eyepiece window) 315 is provided above the monitor 314. By looking into the electronic viewfinder 315, the photographer can determine composition by visually recognizing an optical image of a subject guided from the imaging lens unit 312. As the electronic viewfinder 315, any of the display device 100 and the like can be used.

### Specific Example 2

FIG. 10 is a perspective view illustrating an example of an external appearance of a head mounted display 320. The head mounted display 320 includes, for example, an ear hooking portion 322 to be worn on a head of a user on both sides of an eyeglass-shaped display portion 321. As the display portion 321, any of the display device 100 and the like can be used.

### Specific Example 3

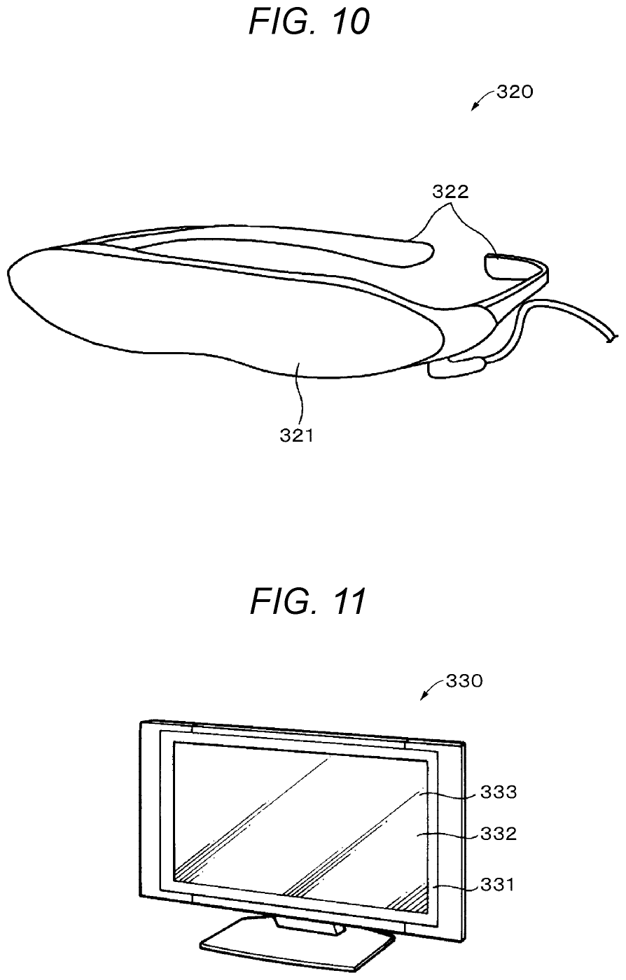

FIG. 11 is a perspective view illustrating an example of an external appearance of a television apparatus 330. The television apparatus 330 includes, for example, an image display screen portion 331 including a front panel 332 and a filter glass 333, and the image display screen portion 331 is any of the display device 100 and the like.

Although the first to third embodiments of the present disclosure and modifications thereof have been specifically described above, the present disclosure is not limited to the first to third embodiments and modifications thereof described above, and can be modified in various ways on the basis of the technical idea of the present disclosure.

For example, the configurations, methods, steps, shapes, materials, numerical values, and the like described in the first to third embodiments and the modifications thereof are merely examples, and different configurations, methods, steps, shapes, materials, numerical values, and the like may be used as necessary.

The configurations, methods, steps, shapes, materials, numerical values, and the like of the first to third embodiments and the modifications thereof can be combined with each other without departing from the gist of the present disclosure.

The materials exemplified in the first to third embodiments and the modifications thereof can be used alone or in combination of two or more kinds unless otherwise specified.

Furthermore, the present disclosure can adopt the following configurations.

(1)

A display device including:
a reflecting portion, an insulating layer, an electrode, and a filter of a predetermined color that are provided in this order in a region around a display region,
in which the reflecting portion and the electrode constitute a resonator structure, and the resonator structure weakens light of the predetermined color.
   (2)

The display device according to (1), in which light of a visible light region is blocked by the filter of the predetermined color and the resonator structure.

(3)

The display device according to (1) or (2), in which the display region includes pixels of a plurality of colors,
the pixels of the plurality of colors include the insulating layer, and
a thickness of the insulating layer in the region around the display region is same as a thickness of the insulating layer in a pixel of one color among the pixels of the plurality of colors.
   (4)

The display device according to (1) or (2), in which the display region includes pixels of a plurality of colors, and
a pixel of one color among the pixels of the plurality of colors includes a filter of a same color as the filter of the predetermined color.
   (5)

The display device according to (3) or (4), in which the pixels of the plurality of colors include a red pixel, a green pixel, and a blue pixel.

(6)

The display device according to any one of (1) to (5), in which the predetermined color is red, green, or blue.

(7)

The display device according to any one of (1) to (6), in which the electrode is provided from the display region to the region around the display region.

(8)

The display device according to (7), in which the electrode is a cathode.

(9)

The display device according to any one of (1) to (8), further including a transparent electrode between the insulating layer and the electrode.

(10)

An electronic apparatus including the display device according to any one of (1) to (9).

(11)

A display device including:
a reflecting portion, a light absorption portion, an electrode, and a color filter that are provided in this order in a region around a display region,
in which the light absorption portion absorbs light that passes through the color filter.
   (12)

The display device according to (11), in which light of a visible light region is blocked by the color filter and the light absorption portion.

(13)

The display device according to (11) or (12), in which the light absorption portion is a light absorption layer having electric conductivity.

(14)

The display device according to (13), further including an insulating layer between the reflecting portion and the light absorption layer,
in which the insulating layer includes a connection portion that electrically connects the reflecting portion and the light absorption layer, and
the light absorption layer and the connection portion include a same material.
   (15)

The display device according to (11) or (12), further including:
an insulating layer including the light absorption portion between the reflecting portion and the electrode; and a lens provided on the color filter,
in which the lens collects external light incident on the color filter onto the light absorption portion.
   (16)

The display device according to (15), in which the light absorption portion electrically connects the reflecting portion and the electrode.

(17)

The display device according to (16), in which the light absorption portion is a via.

(18)

The display device according to any one of (11) to (17), in which the reflecting portion and the electrode constitute a resonator structure, and the resonator structure weakens light of a same color as the color filter.

(19)

The display device according to any one of (11) to (18), in which the color filter is a red filter, a green filter, or a blue filter.

(20)

An electronic apparatus including the display device according to any one of (11) to (19).

### REFERENCE SIGNS LIST

11 First substrate
12 Insulating layer
13 Reflective layer
13A, 13B Reflecting portion
13C Insulating layer
14 Insulating layer
14A, 14B, 14D Via
14C Light absorption layer
14DA End portion
15A First electrode
15B Third electrode
16 Insulating layer
17 Organic electroluminescence layer
18 Second electrode
19 Protective layer
20 Flattening layer
21 Color filter
21R Red filter
21G Green filter
21B, 21B1 Blue filter
22 Filling resin layer
23 Second substrate
24R, 24G, 24B Light emitting element
25R, 25G, 25B Resonator structure
26A, 26B Lens
27 Flattening layer
31 Pad portion
31A Connection terminal
100, 110, 120 Display device
101R, 101G, 101B Subpixel
R1 Display region
R2 Peripheral region
R3 Connection region
310 Digital still camera (electronic apparatus)
320 Head mounted display (electronic apparatus)
330 Television apparatus (electronic apparatus)

1. A display device comprising:
a reflecting portion, an insulating layer, an electrode, and a filter of a predetermined color that are provided in this order in a region around a display region,
wherein the reflecting portion and the electrode constitute a resonator structure, and the resonator structure weakens light of the predetermined color.

2. The display device according to claim 1, wherein light of a visible light region is blocked by the filter of the predetermined color and the resonator structure.

3. The display device according to claim 1, wherein the display region includes pixels of a plurality of colors,
the pixels of the plurality of colors include the insulating layer, and
a thickness of the insulating layer in the region around the display region is same as a thickness of the insulating layer in a pixel of one color among the pixels of the plurality of colors.

4. The display device according to claim 1, wherein the display region includes pixels of a plurality of colors, and
a pixel of one color among the pixels of the plurality of colors includes a filter of a same color as the filter of the predetermined color.

5. The display device according to claim 4, wherein the pixels of the plurality of colors include a red pixel, a green pixel, and a blue pixel.

6. The display device according to claim 1, wherein the predetermined color is red, green, or blue.

7. The display device according to claim 1, wherein the electrode is provided from the display region to the region around the display region.

8. The display device according to claim 7, wherein the electrode is a cathode.

9. The display device according to claim 1, further comprising a transparent electrode between the insulating layer and the electrode.

10. An electronic apparatus comprising the display device according to claim 1.

11. A display device comprising:
a reflecting portion, a light absorption portion, an electrode, and a color filter that are provided in this order in a region around a display region,
wherein the light absorption portion absorbs light that passes through the color filter.

12. The display device according to claim 11, wherein light of a visible light region is blocked by the color filter and the light absorption portion.

13. The display device according to claim 11, wherein the light absorption portion is a light absorption layer having electric conductivity.

14. The display device according to claim 13, further comprising an insulating layer between the reflecting portion and the light absorption layer,
wherein the insulating layer includes a connection portion that electrically connects the reflecting portion and the light absorption layer, and
the light absorption layer and the connection portion include a same material.

15. The display device according to claim 11, further comprising:
an insulating layer including the light absorption portion between the reflecting portion and the electrode; and a lens provided on the color filter,
wherein the lens collects external light incident on the color filter onto the light absorption portion.

16. The display device according to claim 15, wherein the light absorption portion electrically connects the reflecting portion and the electrode.

17. The display device according to claim 16, wherein the light absorption portion is a via.

18. The display device according to claim 11, wherein the reflecting portion and the electrode constitute a resonator structure, and the resonator structure weakens light of a same color as the color filter.

19. The display device according to claim 11, wherein the color filter is a red filter, a green filter, or a blue filter.

20. An electronic apparatus comprising the display device according to claim 11.
